(19) United States
(12) Patent Application Publication
(10) Pub. No.: US 2019/0051710 A1
(43) Pub. Date: Feb. 14, 2019

(54) ARRAY SUBSTRATE, METHOD FOR FABRICATING THE ARRAY SUBSTRATE, AND DISPLAY DEVICE

(71) Applicants: BOE TECHNOLOGY GROUP CO., LTD., Beijing (CN); HEFEI XINSHENG OPTOELECTRONICS TECHNOLOGY CO., LTD., Hefei, Anhui (CN)

(72) Inventor: Minghung HSU, Beijing (CN)

(73) Assignees: BOE Technology Group Co., Ltd., Beijing (CN); Hefei Xinsheng Optoelectronics Technology Co., Ltd., Hefei, Anhui (CN)

(21) Appl. No.: 15/759,707

(22) PCT Filed: Sep. 18, 2017
(86) PCT No.: PCT/CN2017/102015

§ 371 Date: Mar. 13, 2018

(30) Foreign Application Priority Data
Mar. 14, 2017 (CN) 201710150107.8

(51) Int. Cl. H01L 27/32; H01L 51/50; H01L 51/52; H01L 27/12

(52) U.S. Cl. CPC H01L 27/3246; H01L 51/5012; H01L 27/3258; H01L 27/1262; H01L 51/5221; H01L 27/1222; H01L 51/5206

(57) ABSTRACT

The present disclosure relates to an array substrate, a method for fabricating the same and a display device. The array substrate includes a base substrate, and a pixel defining layer having a plurality of protrusions disposed on the base substrate, wherein a region of the array substrate between the protrusions is a pixel region, a first electrode provided on the base substrate in the pixel region, an organic light emitting layer disposed on the first electrode, a second electrode disposed on a light emitting layer, the second electrode having a first portion on a top surface of the protrusions, a second portion in the pixel region, and a third portion on a side surface of the protrusions, and a resistance reducing component provided between the top surface of at least one of the protrusions and the first portion of the second electrode.

### CROSS REFERENCE TO RELATED APPLICATIONS

This patent application is a National Stage Entry of PCT/CN2017/102015 filed on Sep. 18, 2017, which claims the benefit of and priority to Chinese Patent Application No. 201710150107.8 filed on Mar. 14, 2017, the disclosures of which are incorporated herein by reference in their entirety as part of the present application.

### BACKGROUND

The present disclosure relates to the field of display technology, more particularly, to an array substrate, a method for fabricating an array substrate, and a display device.

Organic light emitting display devices (OLED display devices) are widely studied as next-generation displays because of their advantages of low weight, low power consumption, high contrast, high color gamut and the like, as compared to other types of display devices such as liquid crystal display cells, and achieve preliminary application. Another advantage of OLED display devices over liquid crystal display devices is that no backlighting is required. However, there is a problem of IR drop in OLED display devices.

### BRIEF DESCRIPTION

Embodiments of the present disclosure provide an array substrate, a method of fabricating an array substrate, and a display device, so as to at least solve the problems such as voltage drop in OLED devices in the prior art.

Embodiments of the present disclosure provide an array substrate.

A first aspect of the present disclosure provides an array substrate, the array substrate including a base substrate, and a pixel defining layer having a plurality of protrusions disposed on the base substrate, wherein a region of the array substrate between the protrusions is a pixel region, a first electrode provided on the base substrate in the pixel region, an organic light emitting layer disposed on the first electrode, a second electrode disposed on a light emitting layer, the second electrode having a first portion on a top surface of the protrusions, a second portion in the pixel region, and a third portion on a side surface of the protrusions, and a resistance reducing component provided between the top surface of at least one of the protrusions and the first portion of the second electrode.

In an embodiment, the array substrate further includes a buffer layer disposed between the organic light-emitting layer and the second electrode, wherein the buffer layer covers a top surface of the organic light-emitting layer, the side surface of the protrusions, an upper surface of the resistance reducing component, and the top surface of another of the plurality of protrusions not covered by the resistance reducing component.

In an embodiment, at least a part of a projection of the top surface of the resistance reducing component on the plane where a bottom surface of the resistance reducing component is located exceeds an extension range of the bottom surface of the resistance reducing component.

In an embodiment, a cross-sectional shape of the resistance reducing component is an inverted trapezoid.

In an embodiment, the pixel region includes a sub-pixel having a long side and a short side, the resistance reducing component extends in a direction parallel to an extension direction of the short side of the sub-pixel.

In an embodiment, the resistivity of the resistance reducing component is less than the resistivity of the second electrode.

In an embodiment, the resistance reducing component includes a first layer, a third layer, and a second layer disposed between the first layer and the third layer, wherein the first layer includes a transparent conductive oxide, the second layer includes at least one of the following materials: aluminum, silver, or copper, and the third layer includes at least one of the following materials: molybdenum, titanium, indium tin oxide, or indium zinc oxide.

In one embodiment, the resistance reducing component includes a nano-metal material.

In an embodiment, the first electrode includes indium tin oxide, the organic light-emitting layer includes at least one of the following materials: a fluorescent substance, a phosphorescent substance and a quantum dot substance, the buffer layer includes at least one of the following materials: small organic molecules, or aromatic compounds, and the second electrode includes indium zinc oxide, and the pixel definition layer comprises a polymer.

In an embodiment, a thickness of the resistance reducing component ranges from about 100 nm to about 600 nm, a thickness of the buffer layer ranges from about 10 nm to about 20 nm, and a thickness of the second electrode ranges from about 70 nm to about 300 nm.

Another embodiment of the present disclosure provides a display device.

A second aspect of the present disclosure provides a display device including the array substrate described above.

Another embodiment of the present disclosure provides a method of fabricating an array substrate.

A third aspect of the present disclosure provides a method of fabricating an array substrate, including forming a pixel definition layer having a plurality of protrusions on a base substrate, wherein a region of the array substrate between the protrusions is a pixel region, forming a resistance reducing component on a top surface of at least one of the protrusions, forming a first electrode on the base substrate in the pixel region, forming an organic light-emitting layer on the first electrode, and forming a second electrode on the organic light-emitting layer, the second electrode having a first portion on a top surface of the protrusions, a second portion in the pixel region, and a third portion on a side surface of the protrusions.

In an embodiment, the fabricating method further includes: forming a buffer layer between the organic light-emitting layer and the second electrode, wherein the buffer layer covers a top surface of the organic light-emitting layer, the side surface of the protrusions, an upper surface of the resistance reducing component, and a top surface of another of the plurality of protrusions not covered with the resistance reducing component.

In an embodiment, forming the resistance reducing component includes forming the resistance reducing component by using at least two layers of material, wherein an etching rate of an upper layer of the at least two layers of material is less than an etching rate of an underlying layer.

In an embodiment, forming the resistance reducing component includes forming the resistance reducing component by printing a nano metal material.

### BRIEF DESCRIPTION OF THE DRAWINGS

To describe the technical solutions in the embodiments of the present disclosure more clearly, the accompanying drawings of the embodiments are briefly described below. It should be understood that the drawings described below refer only to some embodiments of the present disclosure, and not to the present disclosure of the restrictions, of which:

FIG. 1 is a schematic view of an array substrate according to an embodiment of the present disclosure;

FIG. 2 is a schematic view of an array substrate according to an embodiment of the present disclosure;

FIG. 3 is a schematic view of an array substrate according to an embodiment of the present disclosure;

FIG. 4 is a schematic view of an array substrate according to an embodiment of the present disclosure;

FIG. 5 is a schematic chart of a method for fabricating an array substrate according to an embodiment of the present disclosure;

FIG. 6 is a schematic chart of a method of fabricating an array substrate according to an embodiment of the present disclosure; and

FIG. 7 is a schematic view of a display device according to an embodiment of the present disclosure.

### DETAILED DESCRIPTION

In order to make the technical solutions and advantages of the embodiments of the present disclosure more comprehensible, the technical solutions of the embodiments of the present disclosure are clearly and completely described below with reference to the accompanying drawings. Obviously, the described embodiments are only a part but not all of the embodiments of the present disclosure. Based on the described embodiments of the present disclosure, all other embodiments obtained by those skilled in the art without creative efforts shall also fall within the protection scope of the present disclosure.

As used herein and in the appended claims, the singular form of a word includes the plural, and vice versa, unless the context clearly dictates otherwise. Thus, the references “a”, “an”, and “the” are generally inclusive of the plurals of the respective terms. Similarly, the words “comprise”, “comprises”, and “comprising” are to be interpreted inclusively rather than exclusively.

For purposes of the description hereinafter, the terms “upper”, “lower”, “right”, “left”, “vertical”, “horizontal”, “top”, “bottom”, and derivatives thereof shall relate to the disclosure, as it is oriented in the drawing figures. The terms “overlying”, “atop”, “positioned on” or “positioned atop” means that a first element, such as a first structure, is present on a second element, such as a second structure, wherein intervening elements, such as an interface structure, e.g. interface layer, may be present between the first element and the second element. The term “direct contact” means that a first element, such as a first structure, and a second element, such as a second structure, are connected without any intermediary conducting, insulating or semiconductor layers at the interface of the two elements.

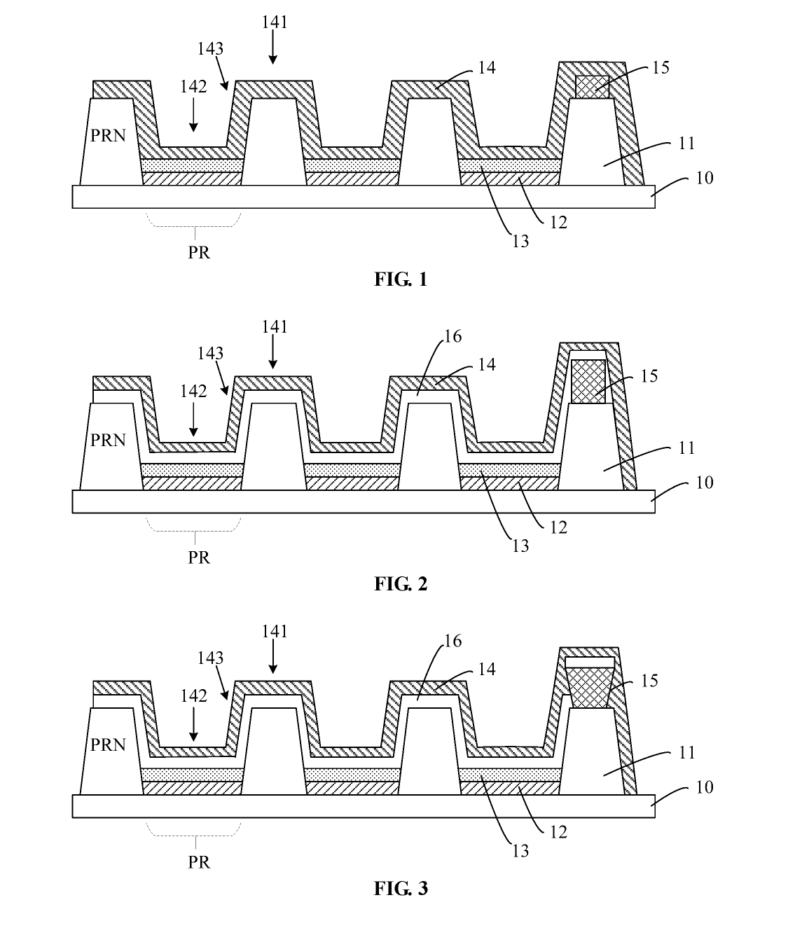

FIG. 1 is a schematic view of an array substrate according to an embodiment of the present disclosure. As shown in FIG. 1, the array substrate includes: a base substrate 10, a pixel defining layer 11 having a plurality of protrusions PRN disposed on the base substrate 10, wherein an area between the protrusions of the array substrate is a pixel region PR, a first electrode 12 disposed on a base substrate in the pixel region PR, an organic light emitting layer 13 disposed on the first electrode 12, and a second electrode 14 disposed on the organic light emitting layer 13. The second electrode 14 has a first portion 141 on the top surface of the protrusion, a second portion 142 in the pixel region and a third portion 143 on the side surface of the protrusion. The array substrate further includes a resistance reducing component 15 disposed between the top surface of at least one protrusion and the first portion of the second electrode.

By providing the resistance reducing component 15, it is possible to reduce the voltage drop caused by the second electrode during the current transfer. This is because the resistance reducing component forms a composite electrode with the first portion of the second electrode to reduce the resistance thereof with respect to the current in the direction extending parallel to the top surface of the base substrate.

It is understood that the first electrode 12 may be used as a pixel electrode and the second electrode 14 may be used as a main electrode when used in a display device such as a display panel.

By such an array substrate including a pixel definition layer having a plurality of protrusions disposed on a base substrate, wherein a region of the array substrate between the protrusions is a pixel region, a first electrode disposed on the base substrate in the pixel region, an organic light emitting layer disposed on the first electrode, a second electrode disposed on the organic light emitting layer, the second electrode having a first portion on the top surface of the protrusion, a second portion in the pixel region and a third portion on the side surface of the protrusion, and a resistance reducing component provided between the top surface of at least one of the protrusions and the first portion of the second electrode, voltage drop caused by the second electrode during a current transfer process may be reduced and display performance may be improved.

FIG. 2 is a schematic view of an array substrate according to an embodiment of the present disclosure. As shown in FIG. 2, in addition to the structure shown in FIG. 1, the array substrate may further include a buffer layer 16 disposed between the organic light-emitting layer 13 and the second electrode 14, wherein the buffer layer 16 covers the top surface, a side surface of the protrusion PRN, an upper surface of the resistance reducing component 15, and a top surface of the protrusion PRN that is not covered by the resistance reducing component. By providing the buffer layer 16, the organic light-emitting layer may have a better injection characteristic in relation to the second electrode.

In one embodiment, at least a part of a projection of the top surface of the resistance reducing component on the plane where a bottom surface of the resistance reducing component is located exceeds an extension range of the bottom surface of the resistance reducing component. This makes at least a part of the side surface of the resistance reducing component uncovered by the buffer layer due to the shielding effect of the top surface when the buffer layer is formed, so that the resistance reducing component can make better electrical contact with the second electrode.

FIG. 3 is a schematic view of an array substrate according to an embodiment of the present disclosure. As shown in FIG. 3, the cross-sectional shape of the resistance reducing component 15 is an inverted trapezoid.

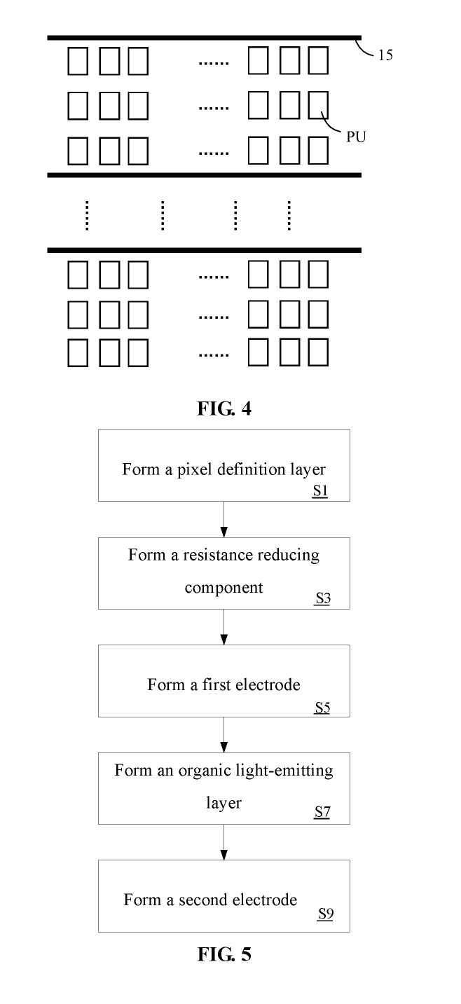

FIG. 4 is a schematic view of an array substrate according to an embodiment of the present disclosure. In FIG. 4, in order to more clearly show the resistance reducing component, it is filled in a different filling pattern from the previous figures. As shown in FIG. 4, the pixel region includes an array of sub-pixels PU having long sides and short sides, and the resistance reducing component 15 extends in a direction parallel to the short side of the sub-pixel. Since the interval between the short sides of the adjacent sub-pixels is larger than the interval between the long sides of the sub-pixels, such setting of the resistance reducing section 15 can reduce the influence on the aperture ratio. It can be understood that the positions and the numbers of the resistance reducing components can also be variously set according to actual needs.

In consideration of conductivity, the resistance reducing component may be set to have a resistivity lower than that of the second electrode.

In an embodiment, the resistance reducing component may include a first layer, a third layer, and a second layer disposed between the first layer and the third layer, wherein the first layer includes a transparent conductive oxide such as ITO, the second layer includes at least one of the following materials: aluminum, silver, or copper, and the third layer includes at least one of the following materials: molybdenum, titanium, indium tin oxide, or indium zinc oxide. In one embodiment, the resistance reducing component may include a nano-metal material.

The first electrode includes indium tin oxide. The organic light emitting layer may include at least one of the following materials: a fluorescent substance, a phosphorescent substance, or a quantum dot substance such as a CdSe quantum dot. The buffer layer may include at least one of the following materials: small organic molecules, or aromatic compounds. The second electrode may include indium zinc oxide (IZO). The pixel defining layer may include a polymer. It is understandable that an electron injection layer, an electron transport layer, a hole transport layer and the hole transport layer may also be respectively disposed on two sides of the organic light-emitting layer which is not described in detail herein for brevity.

The thickness of the resistance reducing component may range from about 100 nm to about 600 nm. The thickness of the buffer layer may range from about 10 nm to about 20 nm. The thickness of the second electrode may range from about 70 nm to about 300 nm.

FIG. 5 is a schematic chart of a method of fabricating an array substrate according to an embodiment of the present disclosure. As shown in FIG. 5, a fabricating method of an array substrate according to an embodiment of the present disclosure includes:

S1: forming a pixel definition layer with a plurality of protrusions on a base substrate, wherein a region of the array substrate between the protrusions is a pixel region;

S3: forming a resistance reducing component on at least one of the protrusions;

S5: forming a first electrode on the base substrate in the pixel region;

S7: forming an organic light-emitting layer on the first electrode; and

S9: forming a second electrode on the organic light-emitting layer, the second electrode having a first portion on a top surface of the protrusions, a second portion in the pixel region, and a third portion on a side surface of the protrusions.

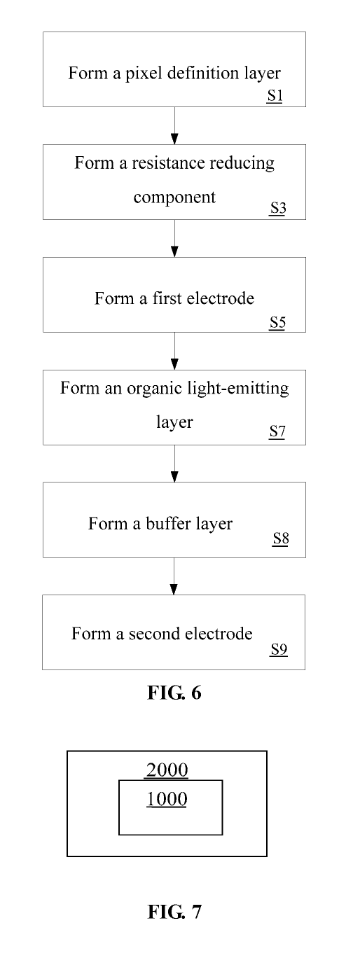

FIG. 6 is a schematic chart of a method of fabricating an array substrate according to an embodiment of the present disclosure. As shown in FIG. 6, a method of fabricating an array substrate according to an embodiment of the present disclosure, in addition to the steps shown in FIG. 5, further includes S8: forming a buffer layer between the organic light-emitting layer and the second electrode, wherein the buffer layer covers the a top surface of the organic light emitting layer, the side surface of the protrusions, an upper surface of the resistance reducing component, and a top surface of another of the protrusions not covered with the resistance reducing component.

In an embodiment, at least a part of a projection of the top surface of the resistance reducing component on the plane where a bottom surface of the resistance reducing component is located exceeds an extension range of the bottom surface of the resistance reducing component. This makes at least a part of the side surface of the resistance reducing component uncovered by the buffer layer due to the shielding effect of the top surface when the buffer layer is formed, so that the resistance reducing component can make better electrical contact with the second electrode. In one embodiment, forming the resistance reducing component may include setting the cross-sectional shape of the resistance reducing component 15 to an inverted trapezoid.

The pixel region includes subpixels having long sides and short sides, and forming the resistance reducing component includes arranging the resistance reducing component in a direction parallel to the short side of the subpixel. This can reduce the influence on the aperture ratio.

In an embodiment, the resistance reducing component may be formed by using at least two layers of material, wherein an etching rate of an upper layer material of the at least two layers of material is less than an etching rate of the an underlying layer, so that the cross section of the resistance reducing component has a shape such as an inverted trapezoid or the like. In this case, the resistance reducing component may include a first layer, a third layer, and a second layer disposed between the first layer and the third layer, wherein the first layer includes a transparent conductive oxide such as ITO, the second layer includes at least one of the following materials: aluminum, silver, or copper, and the third layer includes at least one of the following materials: molybdenum, titanium, indium tin oxide, or indium zinc oxide.

In one embodiment, the resistance reducing component may be formed by printing a nanomaterial. In this case, the resistance reducing component may include a nano-metal material. For example, the resistance reducing component may be formed by printing nano-silver or other nano metal material.

The first electrode may include indium tin oxide. The organic light emitting layer may include at least one of the following materials: a fluorescent substance, a phosphorescent substance, or a quantum dot substance such as a CdSe quantum dot. The buffer layer may include at least one of the following materials: small organic molecules, or aromatic compounds. The second electrode may include indium zinc oxide (IZO). The pixel defining layer may include a polymer. It is understandable that an electron injection layer, an electron transport layer, a hole transport layer and the hole transport layer may also be respectively disposed on two sides of the organic light-emitting layer which is not described in detail herein for brevity.

The organic light emitting material may be formed by a method such as ink jet printing. In order to have better injection characteristics with the second electrode, the buffer layer may be disposed by thermal evaporation. The second electrode may be formed by sputtering. The second electrode and the resistance reducing component may be connected to the power supply's access point (eg, the electroluminescent device power supply negative electrode ELVSS).

Embodiments of the present disclosure also provide a display device and a method of fabricating the display device. Embodiments of the present disclosure also provide a display device, which includes the array substrate as described above. The display device according to the embodiment of the present disclosure may be a display device having a display function such as a display panel, a display, a television, a tablet, a cell phone, a navigator, and the like, which is not limited in the present disclosure.

FIG. 7 is a schematic view of a display device of one embodiment of the present disclosure. As shown in FIG. 7, a display device 2000 according to an embodiment of the present disclosure includes an array substrate 1000 according to the present disclosure. The array substrate may be an array substrate as described above. For example, the array substrate 1000 may include an array substrate as shown in FIGS. 1-4.

Having described certain specific embodiments, these embodiments have been presented by way of example only, and are not intended to limit the scope of the present disclosure. Indeed, the novel embodiments described herein may be embodied in various other forms, furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

1. An array substrate comprising:
a base substrate;
a pixel definition layer having a plurality of protrusions disposed on the base substrate, wherein a region of the array substrate between the protrusions is a pixel region;
a first electrode disposed on the base substrate in the pixel region;
an organic light emitting layer disposed on the first electrode;
a second electrode disposed on the organic fight-emitting layer, the second electrode having a first portion on a top surface of the protrusions, a second portion in the pixel region and a third portion on a side surface of the protrusions; and
a resistance reducing component provided between the top surface of at least one of the protrusions and the first portion of the second electrode.

2. The array substrate according to claim 1, further comprising a buffer layer disposed between the organic light-emitting layer and the second electrode, wherein the buffer layer covers a top surface of the organic light-emitting layer, the side surface of the protrusions, an upper surface of the resistance reducing component, and the top surface of another of the plurality of protrusions not covered by the resistance reducing component.

3. The array substrate according to claim 2, wherein at least a part of a projection of the top surface of the resistance reducing component on a plane where a bottom surface of the resistance reducing component is located exceeds an extension range of the bottom surface of the resistance reducing component.

4. The array substrate according to claim 3, wherein a cross-sectional shape of the resistance reducing component is an inverted trapezoid.

5. The array substrate according to claim 1, wherein the pixel region includes a sub-pixel having a long side and a short side, and wherein the resistance reducing component extends in a direction parallel to an extension direction of the short side of the sub-pixel.

6. The array substrate according to claim 1, wherein a resistivity of the resistance reducing component is smaller than a resistivity of the second electrode.

7. The array substrate according to claim 6, wherein the resistance reducing component includes a first layer, a third layer, and a second layer disposed between the first layer and the third layer, wherein the first layer comprises a transparent conductive oxide;
the second layer comprises at least one of aluminum, silver, and copper; and
the third layer comprises at least one of molybdenum, titanium, indium tin oxide, and indium zinc oxide.

8. The array substrate according to claim 6, wherein the resistance reducing component comprises a nano-metal material.

9. The array substrate according to claim 2, wherein the first electrode comprises indium tin oxide;
the organic light emitting layer comprises at least one of a fluorescent substance, a phosphorescent substance, and a quantum dot substance;
the buffer layer comprises at least one of small organic molecules and aromatic compounds;
the second electrode comprises indium zinc oxide; and
the pixel definition layer comprises a polymer.

10. The array substrate according to claim 9, wherein a thickness of the resistance reducing component ranges from about 100 nm to about 600 nm;
a thickness of the buffer layer ranges from about 10 to about 20 nm; and
a thickness of the second electrode ranges from about 70 to about 300 nm.

11. A display device comprising the array, substrate according to claim 1.

12. A method for fabricating an array substrate comprising:
forming a pixel definition layer having a plurality of protrusions on a base substrate, wherein a region of the array substrate between the protrusions is a pixel region;
forming a resistance reducing component on a top surface of at least one of the protrusions;
forming a first electrode on the base substrate in the pixel region;
forming an organic light-emitting layer on the first electrode; and
forming a second electrode on the organic light-emitting layer, the second electrode having a first portion on a top surface of the protrusions, a second portion in the pixel region, and a third portion on a side surface of the protrusions.

13. The method for fabricating an array substrate according to claim 12, further comprising forming a buffer layer between the organic light-emitting layer and the second electrode, wherein the buffer layer covers a top surface of the organic light emitting layer, the side surface of the protrusions, an upper surface of the resistance reducing component, and a top surface of another of the plurality of protrusions not covered with the resistance reducing component.

14. The method for fabricating an array substrate according to claim 12, wherein forming the resistance reducing component comprises forming the resistance reducing component by using at least two layers of material, wherein an etching rate of an upper layer of the at least two layers of material is less than an etching rate of an underlying layer.

15. The method for fabricating an array substrate according to claim 12, wherein forming the resistance reducing component comprises forming the resistance reducing component by printing a nano-metal material.

16. The method for fabricating an array substrate according to claim 13, wherein forming the resistance reducing component comprises forming the resistance reducing component by printing a nano-metal material.

17. The method for fabricating an array substrate according to claim 13, wherein forming the resistance reducing component comprises forming the resistance reducing component by using at least two layers of material, wherein an etching rate of an upper layer of the at least two layers of material is less than an etching rate of an underlying layer.

18. A display device comprising the array substrate according to claim 2.

19. A display device comprising the array substrate according to claim 3.

20. A display device comprising the array substrate according to claim 4.
